(19) United States
(12) Patent Application Publication
(10) Pub. No.: US 2006/0123301 A1
(43) Pub. Date: Jun. 8, 2006

(54) Transconductance stage operating as an active load for pin electronics

(76) Inventors: James Wey, Arlington, MA (US); Geoffrey Haigh, Boxford, MA (US)

Correspondence Address: John J. Stickevers;Bromberg & Sunstein LLP, 125 Summer Street, Boston, MA, 02110-1618, US

(21) Appl. No.: 11/253,071

(22) Filed: Oct. 18, 2005

Related U.S. Application Data
(60) Provisional application No. 60/619,975, filed on Oct. 19, 2004.

(51) Int. Cl. G01R 31/28; G06F 11/00

(52) U.S. Cl. 714/742

(57) ABSTRACT

A circuit operating as a bridgeless current load in pin testing equipment for testing a pin of a device under test is disclosed. The circuit includes a transconductance stage having at least a first input and a second input and at least one output capable of being coupled to a pin of a device under test. The circuit further includes a first limiting current source coupled to the transconductance stage for sourcing the pin of the device under test to a first current level and a second limiting current source coupled to the transconductance stage for sinking the pin of the device under test to a second current level. The first input receives a commutation voltage and the second input receives a voltage at the output of the transconductance stage from the device under test. When the output voltage is above the commutation voltage, the first limiting current source is active and when the output voltage is below the commutation voltage, the second limiting current source is active. Thus, one of the limiting current sources the device under test with a current and the other limiting current source sinks current from the device under test. In certain embodiments, the gain of the circuit is programmable and therefore, the needed voltage differential to transition between states can be varied and made extremely small. In addition, the gain can be set to program the output resistance of the circuit.

### PRIORITY

The present U.S. patent application claims priority from U.S. provisional patent application No. 60/619,975, filed on Oct. 19, 2004, entitled Operational Transconductance Amplifier Operating as an Active Load of Pin Electronics, which is incorporated herein by reference in its entirety.

### TECHNICAL FIELD AND BACKGROUND ART

The present invention relates to automatic testing equipment (“ATE”) and more specifically to pin testing equipment of integrated circuits. Standard in most ATE is a pin tester that includes a comparator circuit for comparing the input from the pin under test to an expected value, a driver circuit for testing a condition on a pin, an active load for simulating a changing signal, and a precision pin measurement unit (“PPMU”) for performing accurate pin tests. Each of the four described elements is employed with a separate circuit. In the prior art, the active load of the pin testing equipment includes a diode bridge for sourcing and sinking current sources to the device under test (“DUT”). An example of the prior art active load is shown in FIG. 1.

The purpose of the active load 100 is to source or sink the current from the pin 110 of the DUT 115 depending on the logic level of the pin 110. For example, the pin 110 can be in either a high state or a low state. If the pin 110 is in a high state, the active load should sink current from the pin. If the pin is in the low state, the active load 100 should source current to the pin. A commutation voltage 117 provides the point at which the active load begins to switch from sourcing to sinking the pin. The diode bridge 120 of the prior art is capable of quickly performing the switch as the voltage level at the pin transitions above or below the commutation voltage plus the voltage drop across the diode.

The active load diode bridge of FIG. 1 operates in the following manner. When switches 1 and 2 (122, 125) are open the circuit is in the “inhibit” state and no current flows to or from the DUT (115). When switches 1 and 2 (122, 125) are closed and the commutation voltage V_{com} 117 is greater than the voltage at the pin of the device under test V_{dut}, the current Iₒₗ, sources the DUT. When switches I and 2 (122, 125) are closed and the voltage V_{dut} is greater than V_{com}, the current Iₒₕ is sunk from the DUT.

As the logic levels decrease in voltage and approach 1V, the bridge circuit 120 begins to fail, since the voltage differential between V_{com} and V_{dut} must be greater than the “turn-on” voltage for the diodes before the diodes are fully turned on. The turn-on voltage for a typical diode is generally between 0.5 V and 0.6V. As a result, changes in the logic level at V_{dut} may not be great enough to cause the current to be fully sunk or sourced when a diode bridge is used with low logic level voltages.

### SUMMARY OF THE INVENTION

In a first embodiment of the invention there is provided an active load circuit that creates an active load in pin electronic testing equipment without using a diode bridge. The pin electronic testing equipment couples to a pin of a device under test for testing the operating characteristics of the pin. The active load circuit either sources or sinks a current that is provided to the pin of the device under test dependent upon whether the voltage at the pin is either greater than or less than a commutation voltage.

The active load circuit may include a comparison circuit for comparing the commutation voltage to a voltage at the output of the circuit that is coupled to the pin of the device under test. This comparison circuit may be formed from one or more comparators or a differential transistor pair, for example. Coupled to the comparison circuit is a current steering circuit that will steer current from a current source between ground and the pin of the device under test depending on the differential voltage between the commutation voltage and the voltage at the pin of the device under test. The steering circuit may be formed from a CMOS switch or a differential transistor pair. The active load circuit in one embodiment is coupled to a first and a second current limiter. The first current limiter limits the current to be sourced to the pin to a first predetermined value. The second current limiter limits the current to be sunk from the pin to a second predetermined value. In certain embodiments, the first and the second predetermined values have an equal magnitude. In other embodiments, the first and the second predetermined values have different magnitudes.

In a further embodiment, a negative feedback loop is provided between the comparison circuit and the current steering circuit.

In another embodiment, the active load circuit includes a transconductance stage having at least a first input and a second input and at least one output capable of being coupled to a pin of a device under test. In certain embodiments, the transconductance stage may be an operational transconductance amplifier. The circuit also includes a first and a second current limiter. The first current limiter is coupled to the transconductance amplifier for sourcing the pin of the device under test to a first current level and the second current limiter coupled to the transconductance amplifier for sinking the pin of the device under test to a second current level. The current limiter may simply be a current source having a fixed value or the current limiter may be a clamped current source.

The first input receives a commutation voltage and the second input receives the voltage from the pin of the device under test. The active load circuit can source or sink the pin of a device under test that can have voltage logic levels at or below 1 volt.

The transconductance amplifier sources to the pin of the device under test when the commutation voltage is greater than the pin voltage. When the commutation voltage is less than the voltage load current is sunk from the pin of the device under test.

In another embodiment, the gain of the transconductance amplifier is substantially linear. The gain is made substantially linear by adding in one or more linearizing diodes to the circuit. In one embodiment, the linearizing diodes are added at the collectors of the two transistors that form the comparison circuit. The linearizing diodes compensate for the exponential relationship between the emitter base junctions of the transistors of the switching circuit.

In a further embodiment, the gain of the transconductance amplifier can be varied by applying a control signal such as a variable current. The gain of the transconductance amplifier defines the impedance of the amplifier. By adjusting the variable current, the gain can be changed so that the transconductance amplifier operates with quick transitions and approximates an ideal switch or the gain can be set so that the transconductance amplifier appears as a very large resistor. The gain can also be varied between the two extremes so that the effective output resistance of the transconductance amplifier can be set to a desired level.

### BRIEF DESCRIPTION OF THE DRAWINGS

The foregoing features of the invention will be more readily understood by reference to the following detailed description, taken with reference to the accompanying drawings, in which:

FIG. 1 is a prior art active load that includes a diode bridge;

FIG. 2 is an active load using an operational transconductance amplifier (OTA);

FIG. 3 is graph showing that GM is substantially linear for this circuit between Iₒₗ and Iₒₕ;

FIG. 4 shows a schematic diagram of one embodiment of the invention;

FIG. 5 shows another embodiment of the active load circuit for use with pin testing equipment that does not include a diode bridge;

FIG. 6 shows a graph demonstrating that by varying the resistances within the active load circuit, the gain GM can be varied so that the circuit has shorter transition times or behaves like a resistance;

FIG. 7 shows another embodiment of the invention wherein the current is increased by a factor;

FIG. 8 is an embodiment of a transconductance amplifier that has a variable gain Gm that may be adjusted by changing a variable current source; and

FIG. 9 shows an embodiment of a transconductance amplifier with an enable/disable component.

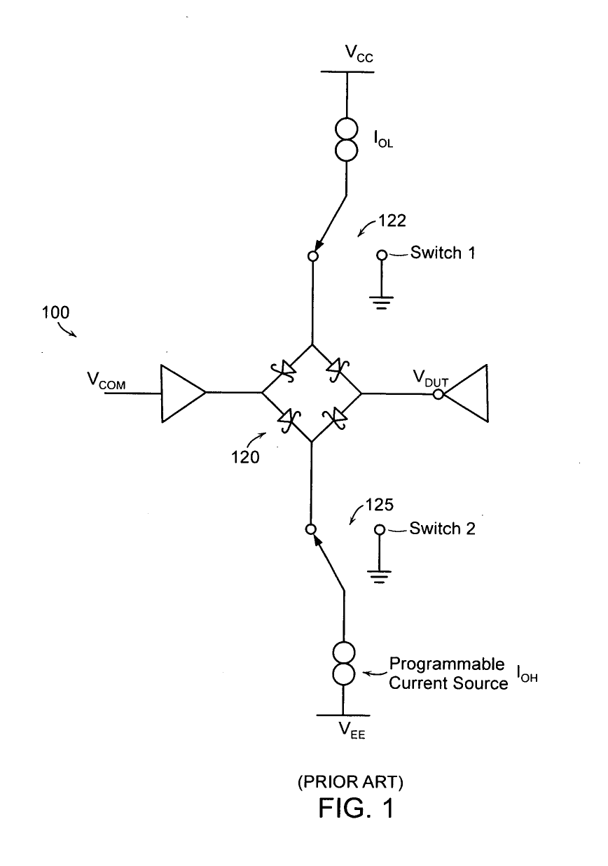

### DETAILED DESCRIPTION OF SPECIFIC EMBODIMENTS

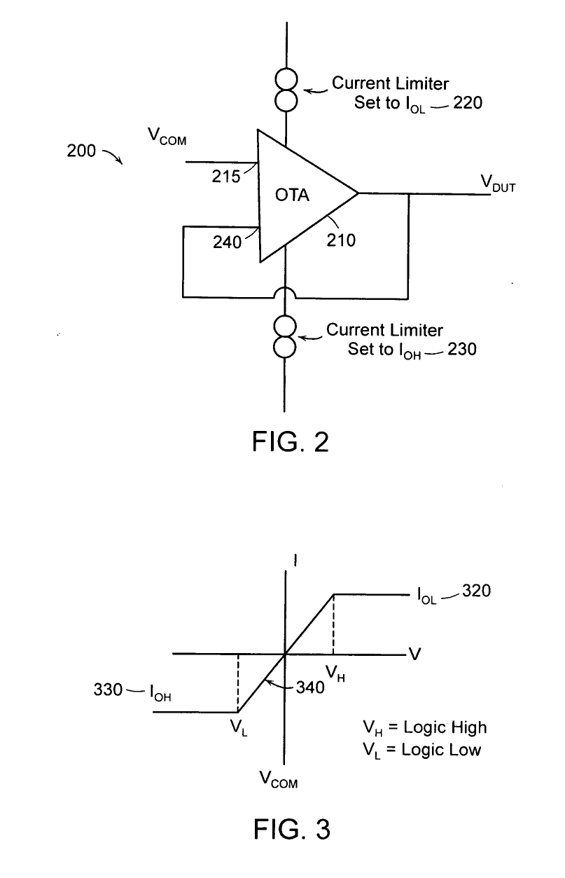

FIG. 2 is block diagram showing a circuit configuration for an active load 200 that can be implemented in automated testing equipment for pin electronics. The active load circuit provides a signal to a pin of the DUT without employing a diode bridge. The circuit includes a transconductance stage, such as an operational transconductance amplifier (OTA) 210 as shown in the Fig. The OTA receives at its inputs (215, 240)a first voltage and a second voltage and based upon the difference between the two voltages produces a proportional output current up to a maximum current. A transconductance/transresistance amplifier can also be made that receives current at its inputs and produces a voltage at its output that is proportional to the difference between the input currents. Thus, a transconductance amplifier receives in at its input either a differential signal of current or voltage and produces at its output a proportional voltage or current. (V in I out, I in V out). In the present embodiment as shown, the transconductance amplifier receives in a voltage signal and outputs a proportional current.

In the embodiment as shown, the OTA 210 is provided with two limiting current sources 220, 230. The limiting current sources may be current sources capable of producing a maximum current, a current source with clamping circuitry, or a programmable current source. The limiting current sources 220, 230 are used to set the maximum and minimum currents that will be produced at the output of the OTA 210 upon a full transition of the voltage logic levels at the pin of the DUT. The first limiting current source 220 is set to Iₒₗ and the second limiting current source is set to Iₒₕ. In the present embodiment, V_{com} is set to be at a value that is approximately halfway between a logic high level and a logic low level. For example, if a logic high voltage is 3 Volts and a logic low level is −3 Volts, V_{com} would be approximately 0 Volts. It should be understood by one of ordinary skill in the art that the commutation voltage, V_{com} can be set to any value that is between a logic high level and a logic low level.

In the present embodiment, the output of the OTA 210 is tied to the second input in a feedback loop 240. Thus, the voltage level at the input follows the output. The difference between the output voltage, which is the voltage at the DUT, V_{dut}, and V_{com} is used to produce a proportional output current. When the output voltage is greater than V_{com}, Iₒₕ sinks the DUT. When the output voltage is less than V_{com}, Iₒₗ, sources the DUT.

FIG. 3 is a graph showing the input and output characteristics of one embodiment of the invention. The output locks to either Iₒₗ, or Iₒₕ (320, 330) and will go no higher due to the current limitation of the limiting current sources. In the present configuration, Iₒₗ, and lₒₕ (320, 330) may be at the same but inverse current levels (1 mA, −1 mA) or at completely different current levels (10 mA, −15 mA). When the output voltage is either fully high or fully low, the current is fully high or low. During the transition, the gain is linear 340. The linearity in the transition between a logic high level and a logic low level is due to a linear Gm (transconductance gain) for the OTA. The gain or GM is made to be approximately linear by incorporating resistors and diodes within the transconductance amplifier to define Gm.

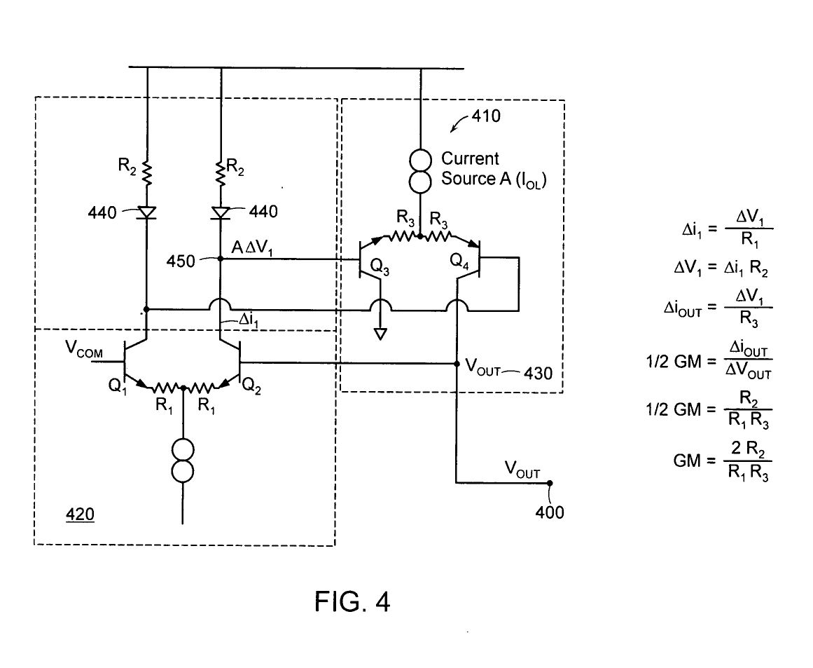

FIG. 4 shows a partial circuit diagram showing an implementation of the circuit of FIG. 2. Although bi-polar transistors are depicted, the circuitry can be implemented with field effect transistors. In the embodiment that is shown, only half of the circuit is provided. The other half of the circuit is the mirror image of the shown circuit, except that the NPN transistors are replaced by PNPs. Another difference is that the diodes of the PNPs must point away from the collectors of the transistors. Both circuits are coupled at the output node 400. Thus, the Gm for the shown circuit is half of the Gm for the whole active load circuit. In the present configuration, only limited current source Iₒₗ (410) is provided. The mirror image of the circuit includes current limiter Iₒₕ.

Simply stated, the circuitry can be viewed as a differential sensing pair (Q1, Q2) 420 that is used with a differential current steering pair (Q3, Q4) 430 where negative feedback is applied between the current steering pair and the sensing pair. The negative feedback occurs between the base of Q2 and the collector of Q4.

The circuit includes an OTA that is formed from the sensing differential pair of transistors Q1 and Q2 and the current switching pair Q3 and Q4. Q1 receives as an input to its gate the commutation voltage V_{com}. The transistor Q2 receives in the voltage, V_{dut} from the pin of the DUT. A first linearizing resistor R1 is placed at the output of the emitter of Q2. A second linearizing resistor R2 is coupled between the positive voltage rail and the collector of Q2. These resistors may be either real resistors or equivalent resistors. A compensation diode 440 is placed between the collector of the transistors and the resistors. The linearizing diode 440 linearizes the transconductance output, so that Gm is substantially linear. If the diodes are not present, the circuit will behave (more logarithmically) like an RC circuit and the transitions between states will take longer. It should be understood by one of ordinary skill in the art that the transconductance amplifier would still operate without the linearizing diodes and therefore the output of the transconductance amplifier would have a logarithmic output and therefore would take longer to reach the maximum output current.

At node A 450, another differential pair (the current steering pair) 430 is electrically coupled (Q3, and Q4). Transistors Q3 and Q4 form a current steering switch 430. The base of transistor Q3 is coupled to node A 450. Another linearizing resistor R3 is coupled to the emitter of Q3. The base of transistor Q4 is electrically coupled to the collector of Q1.

Because of the above described configuration, if V_{com} is greater than V_{dut} the transistor Q1 is turned on and transistor Q2 is turned off for the differential pair. Thus, current flows through Q1 and pulls the base voltage of Q4 down and turns Q4 on. Current source A sources V_{dut} up to the maximum current Iₒₗ.

When the V_{dut} is greater than V_{com}, Q2 is on and the base voltage of Q3 is pulled down turning on Q3. Q4 is pulled up through the feedback connection between the collector of Q1 and the base of Q4. Thus, the current source A (410) flows to ground through Q3.

The mirror circuit provides the inverse. Wherein when V_{dut} is greater than V_{com} a second current source, current source B (not shown), is on and this current source sinks current from the DUT up to Iₒₕ. When V_{com} is greater than V_{dut} then the second current source B is provided to ground.

The circuit of FIG. 4 appears as an effective resistor to the pin 400 of the device under test. The Gm of the circuit is defined as 2R₂/R₁R₃ which is 1/R for the circuit. Thus, the gain Gm is determined only by the size of the effective resistances and the effective resistance is only determined by the resistors. By increasing the size of R₂ and decreasing the size of R₁ and R₃, the slope of the Gm curve increases. As the slope increases, the differential change in V to fully turn on the transistors (Q1 and Q2) and source or sink the pin of the DUT decreases. The circuit behaves more and more like an ideal switch switching nearly instantaneously between a low state and a high state (or high and low state) when the voltage level V_{com} exceeds the voltage level V_{dut} by ΔV (or V_{dut} exceeds the voltage of V_{com} by ΔV). As a result by defining the resistances in this way the circuit will switch states with a fast transition time comparable to the transition time found in the prior art diode bridge systems. One advantage of the present invention as embodied in FIG. 4 is that ΔV can be decreased in order to cause a quicker transition and thus, because ΔV can be varied, the logic level can continue to decrease in size to values well below 1V. Therefore, as the logic level decreases, the circuit can be configured so that very small ΔV is needed for the circuit to switch between sourcing and sinking current.

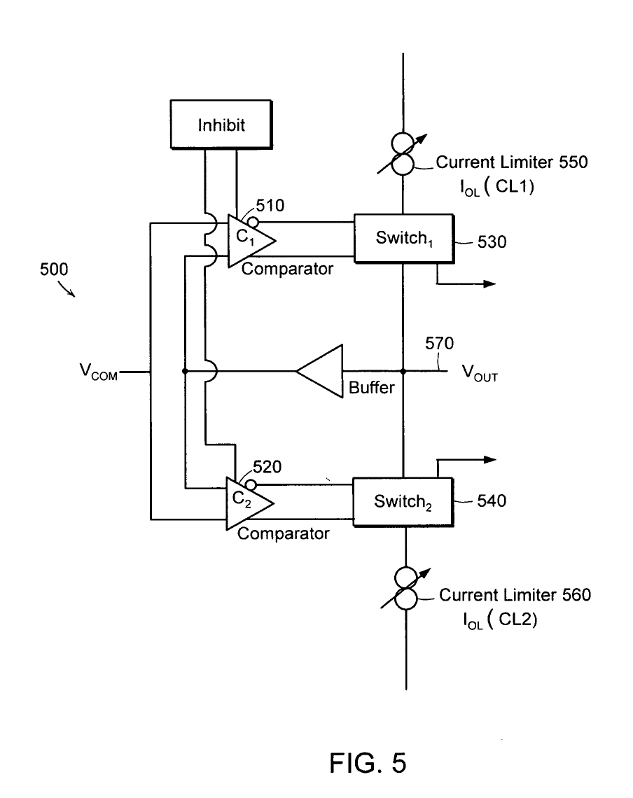

FIG. 5 shows another embodiment of the present invention. The circuit 500 is built using two comparators C1 and C2 (510, 520). If V_{com} is greater than V_{dut} the comparator C1 outputs an enable signal to switch 1 (530) and thus the current limiter CL1 (550) sources current to the DUT 570 up to the current Iₒₗ. The enable signal may be any signal that causes switch 1 (530) to switch the current source from ground to the pin of the DUT. At the same time, comparator C2 (520) produces a signal to the switch that causes current limiter CL2 (560) to direct the current to ground. When V_{dut} is greater than V_{com} the inverse occurs. Comparator C1 (510) produces a signal to switch 1 that causes the current from CL1 (550) to be directed to ground. Comparator C2 (520) produces an output signal that switches switch 2 from ground to CL2 (560) so that current is sunk from the DUT up to Iₒₕ.

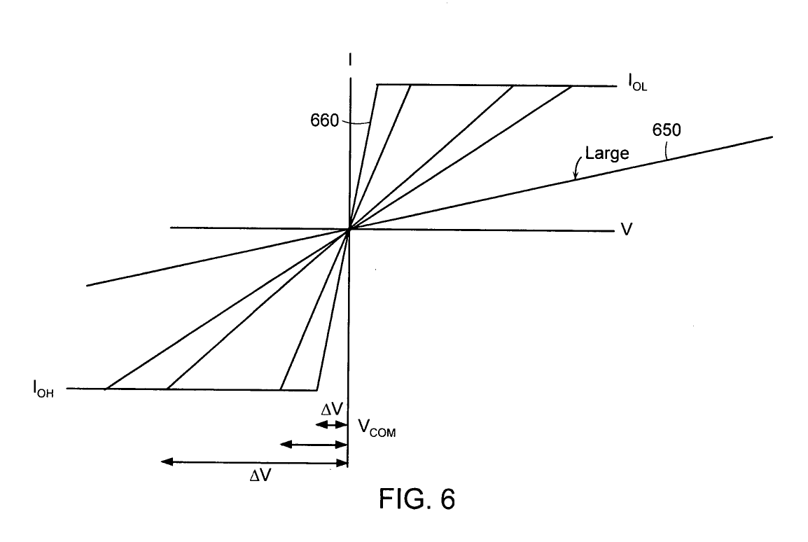

The circuit shown in FIG. 4 can also be used as a passive load wherein rather than setting the values of R₁, R₂, and R₃ so that the slope is nearly vertical as indicated by line 660 on FIG. 6, the values can be set to make the slope more horizontal and therefore the circuit would appear more like a large resistor as indicated by line 650. The slope of the curve defining the transfer function between Iₒₗ and Iₒₕ can be varied by changing the values of the three resistors within the circuit. Thus, the effective resistor connected from the DUT pin to V_{com} while in the transition region between Iₒₗ and Iₒₕ can be varied as desired. Similarly, the larger the effective resistance, the greater the change in V that is required to switch the state. Again, it should be appreciated that the circuits shown throughout this application may be built with either bi-polar or field effect transistors.

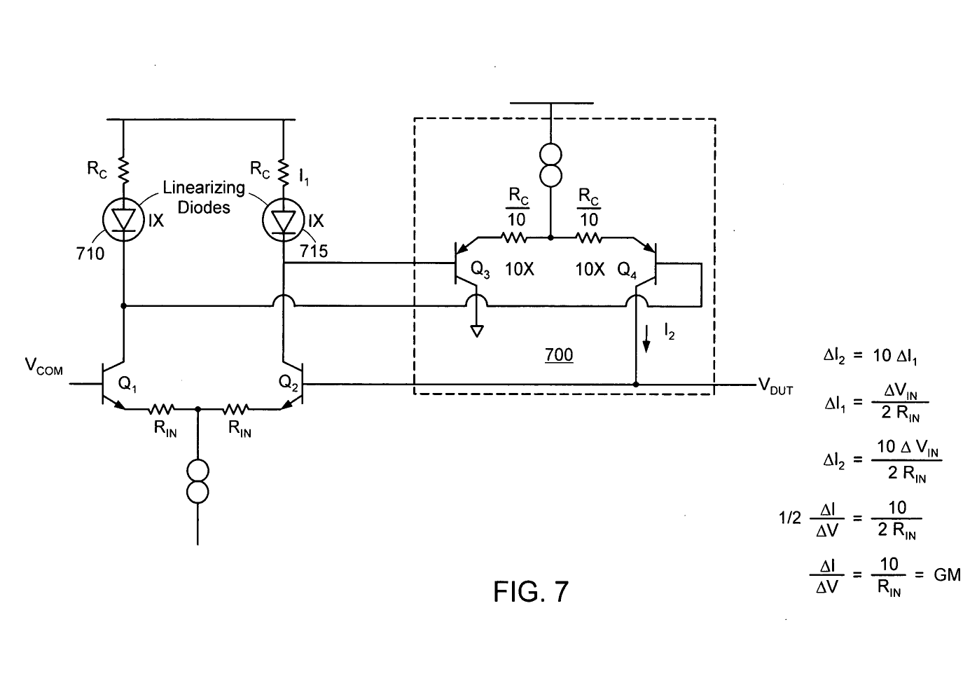

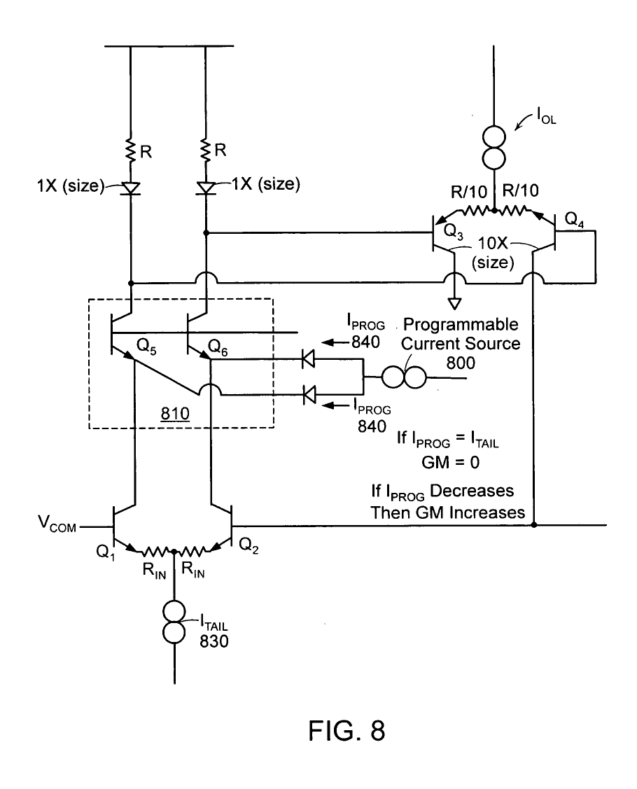

FIG. 7 shows another embodiment of the invention. In this embodiment, the current gain between I1 and I2 is defined in part by the area of the linearizing diodes and the emitter base function of the transistors of the current steering switch 700. In the embodiment that is shown, the linearizing diodes 710, 715 have an area of 1 (L×W) whereas the emitter base junction area of Q3 and Q4 is 10× that of the linearizing diodes 710, 715. Thus, I2 is ten times that of I1. Thus, the transition between Iₒₗ and Iₒₕ happens quicker with a smaller differential change between V_{com} and V_{dut}.

In another embodiment, the transconductance amplifier can be configured such that the gain of the transconductance amplifier can be varied by an external signal, which in the preferred embodiment is a programmable current source 800 as shown in FIG. 8. Thus, by varying the level of the input signal the slope of the transfer function can be shifted from horizontal where the circuit appears to have relatively large impedance to a circuit that operates similar to an ideal switch in which a small change in voltage level will cause a switch in current levels.

The transconductance amplifier that is formed from the two differential pairs (Q1, Q2 and Q3, Q4) is supplemented with a cascode circuit 810 in order to speed up the transition. The cascode 810 forms part of a Gilbert multiplier, which is known to one of ordinary skill in the art. A programmable current source 800 producing Iprogram 840 is coupled to the emitters of the cascode transistor pair (Q5, Q6) 810. Depending upon the difference between the biasing current Itail 830 and the programming current Iprogram 840 the gain of the circuit is varied. For example, if Itail is equal to Iprogram then the gain of the circuit is zero and the input impedance appears to be nearly infinite. As Iprogram 840 is varied between zero current and Itail 830, the amount of current that flows through the differential pair Q1 and Q2 is varied. As a result, the current can be set to be set between zero current when Itail=Iprogram and maximum current when Iprogram=0. Thus, the slope of the transfer function varies wherein the slope will decrease as Iprogram is increased, thereby increasing the effective resistance.

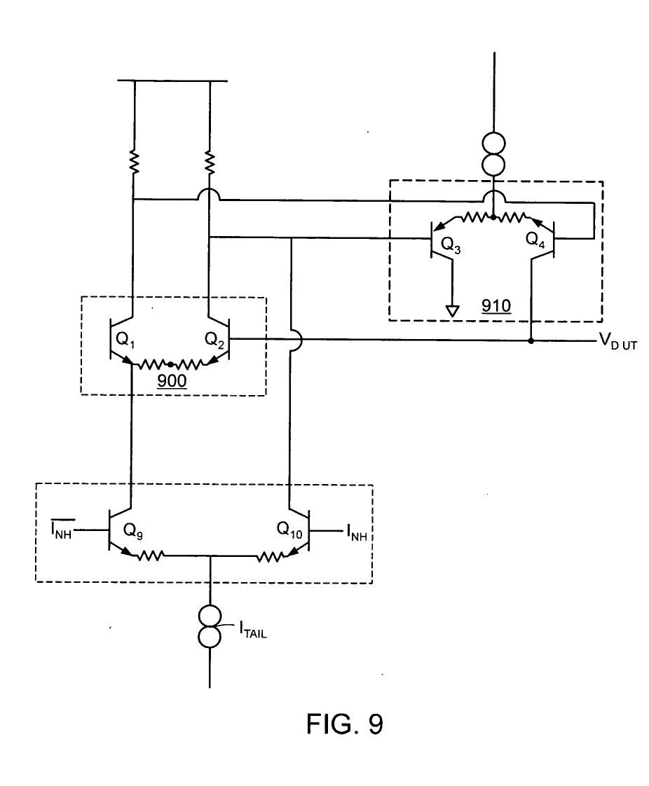

An inhibit function can also be added to the circuit as shown in FIG. 9. The inhibit function is provided by adding an additional differential pair of transistors (Q9, Q10) that is coupled at one of the collectors to the emitter junction of the comparison transistor pair (Q1, Q2) 900. The collector of Q10 is also coupled to the base of the steering transistor pair (Q3, Q4) 910. When the inhibit function is enabled, an inhibit signal is provided to the base of transistors (Q9, Q10) 920. By turning off transistor Q9, Itail cannot flow through either Q1 or Q2 and therefore, the differential signal does not effect whether current is sourced or sunk to the DUT. It should be noted that no linearizing diodes are present within this embodiment. Linearizing diodes may be added to the collectors of Q1 and Q2 to linearize the transfer function. However, the shown embodiment will still function as a transconductance amplifier and provide an output current that is proportional to the differential input voltage. The transfer function of this embodiment will be less linear and will behave more logarithmically.

The present invention may be embodied in other specific forms without departing from the true scope of the invention. The described embodiments are to be considered in all respects only as illustrative and not restrictive.

What is claimed is:

1. A circuit operating as a bridgeless current load in pin testing equipment for testing a pin of a device under test, the circuit comprising:
a transconductance stage having at least a first input, a second input, and at least one output, the output capable of being coupled to a pin of a device under test;
a first limiting current source coupled to the transconductance stage for sourcing the pin of the device under test to a first current level;
a second limiting current source coupled to the transconductance stage for sinking the pin of the device under test to a second current level;
wherein the first input receives a commutation voltage and the second input receives a voltage at the output of the transconductance stage.

2. The circuit according to claim 1, wherein the device under test operates at a sub-one volt logic level, and wherein the circuit is capable of providing a switching load to the pin of the device under test.

3. The circuit according to claim 1, wherein a feedback loop exists between the output of the transconductance stage and the second input.

4. The circuit according to claim 3, wherein the first limiting current source limits the first current to a first preset value and wherein the second limiting current source limits the second current to a second preset value.

5. A circuit according to claim 4, wherein the transconductance stage has an associated transconductance gain that is substantially linear between the first preset value and the second preset value.

6. The circuit according to claim 4, wherein the first preset value does not have to be equal to the second preset value

7. The circuit according to claim 4, wherein the transconductance stage switches between the first and the second limiting current source when a voltage difference between the voltage level at the output and a commutation voltage level at the first input switches from positive to negative.

8. The circuit according to claim 4 wherein the transconductance stage switches between the second and the first limiting current source when a voltage difference between the voltage level at the output and a commutation voltage level at the first input switches from negative to positive.

9. The circuit according to claim 1, wherein the transconductance stage includes a differential transistor pair.

10. The circuit according to claim 9, wherein the differential transistor pair includes a first bipolar transistor and a second bipolar transistor each having a base, collector, and emitter.

11. The circuit according to claim 10 wherein the base of the first bipolar transistor of is coupled to the input of the transconductance stage and the base of the second bipolar transistor is coupled to the output of the transconductance stage.

12. The circuit according to claim 11 wherein the first limiting current source includes a differential transistor pair.

13. The circuit according to claim 12, wherein the differential transistor pair includes a first and a second bipolar transistor each having a base, collector and emitter.

14. The circuit according to claim 13, wherein the base of the first bipolar transistor of the first limiting current source is coupled to the collector of the second bipolar transistor of the transconductance stage and wherein the base of the second bipolar transistor of the first limiting current source is coupled to the collector of the first bipolar transistor of the transconductance stage.

15. A method for creating a passive load defining a desired resistance presented to a device under test using active elements, the method comprising:
providing a transconductance amplifier, having a plurality of inputs and an output, the output fed back to a first of the inputs and an input voltage fed to a second of the inputs, wherein the transconductance amplifier has a gain defined by an effective resistance due to resistances internal to the transconductance amplifier; and
varying the internal resistances and therefore the effective resistance until the desired resistance is achieved.

16. The method according to claim 15, wherein the gain of the transconductance amplifier is substantially linear between a first current level and a second current level.

17. The method according to claim 16 wherein the first current level is a maximum current and the second current level is a minimum current.

18. The method according to claim 16 wherein the transconductance amplifier includes at least one diode for linearizing the gain.

19. The method according to claim 15 wherein the transconductance amplifier includes a first differential transistor pair, the first differential transistor pair having an input bipolar transistor coupled to the input voltage and an output bipolar transistor coupled to an output voltage wherein the collector of each bipolar transistor includes a resistance and the emitter of each bipolar transistor includes a resistance.

20. The method according to claim 19, wherein the transconductance amplifier includes a second differential transistor pair, the second differential transistor pair having a first bipolar transistor having a base coupled to the collector of the input bipolar transistor and a second bipolar transistor having a base coupled to the collector of the output bipolar transistor, the emitters of the first and second bipolar transistors coupled to a resistance.

21. The method according to claim 20 wherein the gain of the transconductance amplifier is defined by the ratio of the resistance coupled to the emitters of the second differential transistor pair and the resistances coupled to the collectors and emitters of the first differential transistor pair.

22. A bridgeless active load having an input and an output, the bridgeless active load comprising:
a comparison circuit for comparing an input voltage to a voltage at the output defining a differential voltage;
a current steering circuit steering current from a current source between a first current path and the output depending on the differential voltage.

23. The bridgeless active load according to claim 22, wherein the comparison circuit includes a differential transistor pair.

24. The bridgeless active load according to claim 22, wherein the comparison circuit includes one or more comparators.

25. The bridgeless active load according to claim 22, wherein the steering circuit includes a plurality of CMOS switches.

26. The bridgeless active load according to claim 22, wherein the steering circuit includes a differential transistor pair.

27. The method according to claim 15 wherein the transconductance amplifier includes a first differential transistor pair, the first differential transistor pair having an input field effect transistor coupled to the input voltage and an output field effect transistor coupled to an output voltage wherein the source of each field effect transistor includes a resistance and the drain of each field effect transistor includes a resistance.
